(19) United States
(12) Patent Application Publication
(10) Pub. No.: US 2018/0294179 A1
(43) Pub. Date: Oct. 11, 2018

(54) APPARATUS FOR SUBSTRATE BEVEL AND BACKSIDE PROTECTION

(71) Applicant: ACM Research (Shanghai) Inc., Shanghai (CN)

(72) Inventors: Xi Wang, Shanghai (CN); Hui Wang, Shanghai (CN)

(73) Assignee: ACM Research (Shanghai) Inc., Shanghai (CN)

(21) Appl. No.: 15/573,925

(22) PCT Filed: May 14, 2015
(86) PCT No.: PCT/CN2015/078925

§ 371 Date: Nov. 14, 2017

(51) Int. Cl. H01L 21/683; H01L 21/67

(52) U.S. Cl. CPC H01L 21/6838; H01L 21/67023

(57) ABSTRACT

The present invention provides an apparatus for substrate bevel and backside protection. The apparatus includes a vacuum chuck (103), a protecting apparatus, a gas supplying apparatus (114), a spin actuator (115) and a vertical actuator (113). The vacuum chuck (103) holds and positions a substrate. The protecting apparatus has s base portion and a supporting portion (104). The supporting portion (104) is set close to the substrate (101). The supporting portion (104) has a plurality of injecting ports (107) for delivering gas to the gap (105) and a plurality of releasing ports (108) for releasing the gas out of the gap (105). The base portion has a plurality of gas lines (111) and each gas line (111) is connected to one injecting port (107). The gas supplying apparatus (114) supplies the gas to the gas lines (111) of the protecting apparatus. The plurality of injecting ports (107) delivers the gas to the gap (105) for forming a positive gas pressure in the gap (105), and the gas in the gap (105) serves as a gas curtain to protect the bevel and back-side of the substrate(101). The spin actuator (115) drives the vacuum chuck (103) and the protecting apparatus to rotate. The vertical actuator (113) drives the vacuum chuck (103) to move vertically.

### BACKGROUND OF THE INVENTION

### 1. Field of the Invention

The present invention generally relates to a substrate processing apparatus, and more particularly to an apparatus making use of gas curtain to protect bevel and backside of a substrate, preventing the bevel and backside of the substrate from damage during wet process such as cleaning, etching, developing, photo resist coating or removing.

### 2. The Related Art

During a semiconductor device fabrication process, bevel and backside of a substrate need to be protected from the damage of processing chemicals. In some applications, the bevel and backside of the substrate is sensitive to the processing chemicals. When front side of the substrate is processed, such as cleaning, etching, developing, photo resist coating or removing, one of the challenges is to keep the bevel and backside of the substrate from being damaged.

In one case, a substrate, such as a wafer, is bonded on a substrate carrier made of semiconductor substrate, glass or sapphire, and the substrate will be de-bonded from the substrate carrier after a series of desired processes. In a specific wet process, the surface of the substrate is processed by a chemical, because there is no effective apparatus or method to protect the bevel and backside of the substrate carrier, the bevel and backside of the substrate carrier will be damaged by the chemical during the surface of the substrate is processed by the chemical. However, the substrate carrier should be protected to avoid this damage due to the following steps or a substrate carrier reclaim requirement.

Therefore, there is a need for an apparatus for substrate bevel and backside protection during the front side of the substrate being processed.

### SUMMARY

The present invention provides an apparatus for substrate bevel and backside protection. The apparatus includes a vacuum chuck, a protecting apparatus, a gas supplying apparatus, a spin actuator and a vertical actuator. The vacuum chuck holds and positions a substrate. The protecting apparatus has a base portion and a supporting portion. The supporting portion is set close to the substrate and a gap is formed between the supporting portion and the substrate. The supporting portion has a plurality of injecting ports for delivering gas to the gap and a plurality of releasing ports for releasing the gas out of the gap. The base portion has a plurality of gas lines and each gas line is connected to one injecting port. The gas supplying apparatus supplies the gas to the gas lines of the protecting apparatus. The plurality of injecting ports delivers the gas to the gap for forming a positive gas pressure in the gap, and the gas in the gap serves as a gas curtain to protect the bevel and backside of the substrate. The spin actuator drives the vacuum chuck and the protecting apparatus to rotate. The vertical actuator drives the vacuum chuck to move vertically.

The present invention utilizes the protecting apparatus to form the gas curtain for protecting the bevel and backside of the substrate, avoiding damaging the bevel and backside of the substrate when the substrate is processed.

### BRIEF DESCRIPTION OF THE DRAWINGS

The present invention will be apparent to those skilled in the art by reading the following description of preferred embodiments thereof, with reference to the attached drawings, in which:

FIGS. 1A and 1B are cross-sectional views showing an apparatus for substrate bevel and backside protection according to an exemplary embodiment of the present invention;

FIG. 1C is a sectional view taken along line A-A in FIG. 1A;

FIG. 1D is a sectional view taken along line B-B in FIG. 1A;

FIG. 2A is a top view showing an apparatus for substrate bevel and backside protection according to an exemplary embodiment of the present invention;

FIG. 2B is another top view showing an apparatus for substrate bevel and backside protection according to another exemplary embodiment of the present invention;

FIGS. 3A to 3C are cross-sectional views showing an apparatus for substrate bevel and backside protection according to another exemplary embodiment of the present invention; and

FIG. 3D is a sectional view taken along line A-A in FIG. 3A.

### DETAILED DESCRIPTION OF EMBODIMENTS

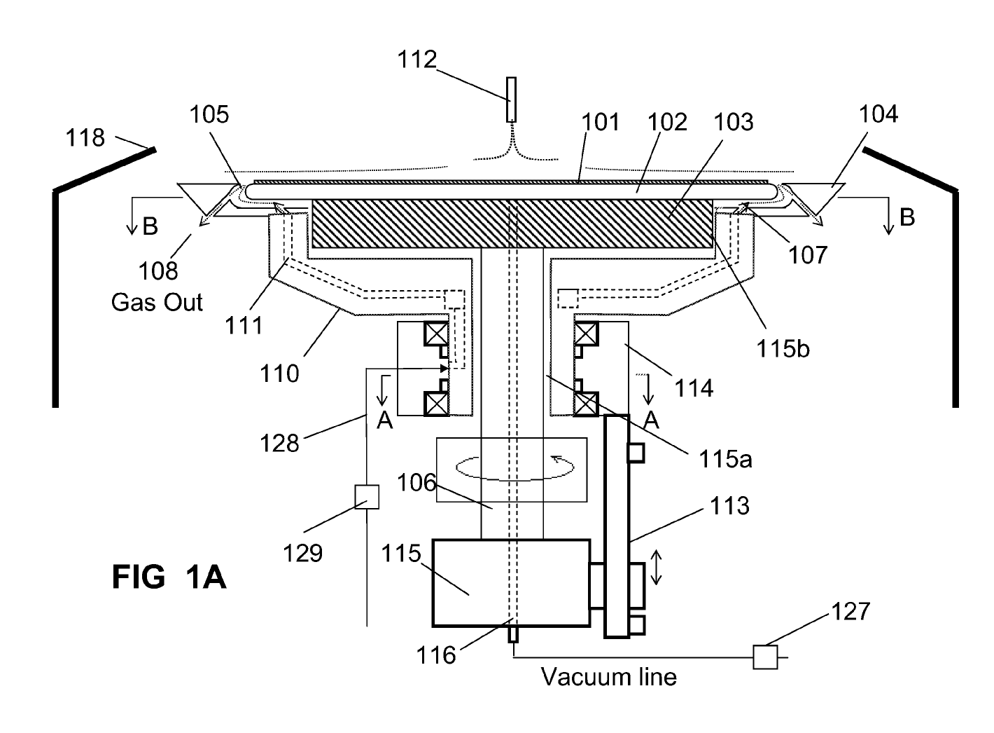

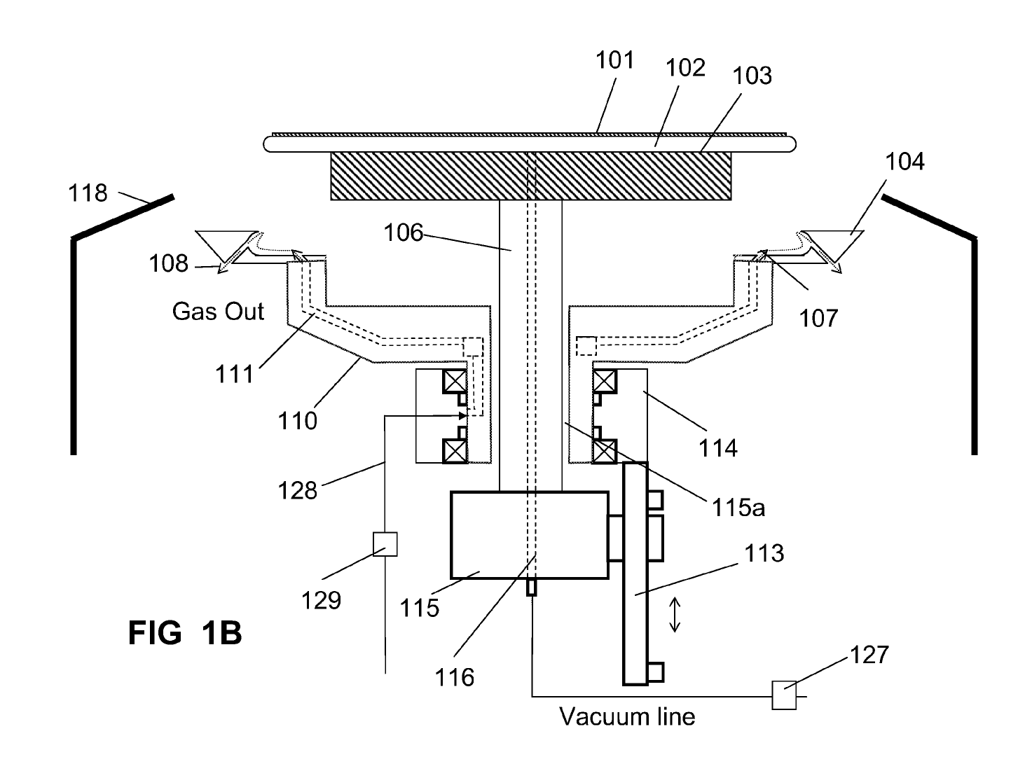

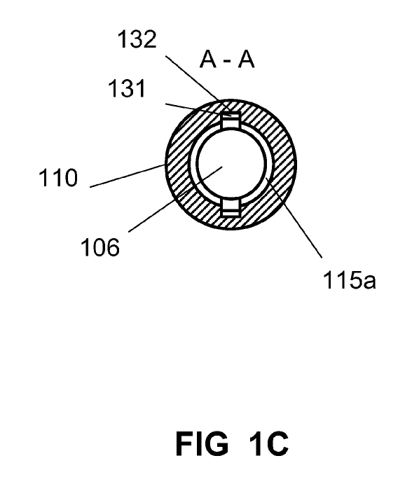

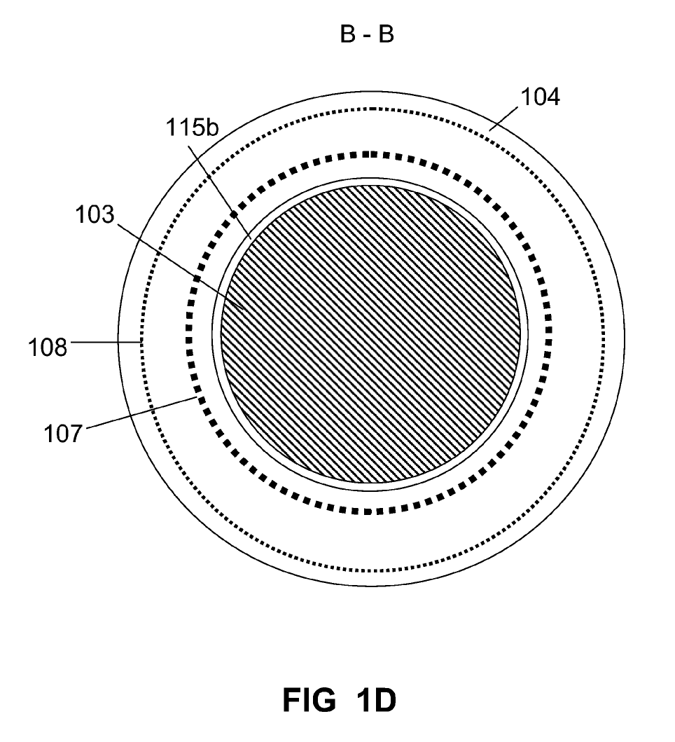

Referring to FIG. 1A to FIG. 1D, an apparatus for substrate bevel and backside protection according to an exemplary embodiment of the present invention is illustrated. The apparatus includes a vacuum chuck 103 for holding and positioning the backside of a substrate by vacuum suction, a protecting apparatus surrounding the periphery of the vacuum chuck 103 for protecting the bevel and backside of the substrate, a gas supplying apparatus 114 supplying gas to the protecting apparatus to form gas curtain for protecting the bevel and backside of the substrate, a spin actuator 115 connecting to the vacuum chuck 103 for driving the vacuum chuck 103 and the protecting apparatus to rotate, and a vertical actuator 113 for driving the vacuum chuck 103 to move vertically.

The vacuum chuck 103 is connected to the spin actuator 115 through a rotary spindle 106. One end of the rotary spindle 106 is connected to the vacuum chuck 103 and the other end of the rotary spindle 106 is connected to the spin actuator 115. A vacuum line 116 passes though the center of the spin actuator 115 and the center of the rotary spindle 106 and extends to the vacuum chuck 103, so as to provide the vacuum suction for holding and positioning the substrate. A pressure regulator 127 is disposed on the vacuum line 116 for controlling the pressure of the vacuum line 116.

The protecting apparatus includes a base portion 110 and a supporting portion 104 which is mounted on the base portion 110 and detachable from the base portion 110. The supporting portion 104 has a plurality of injecting ports 107 and a plurality of releasing ports 108. The plurality of injecting ports 107 and releasing ports 108 are respectively arranged on a circle on the supporting portion 104. Each injecting port 107 is inclined and formed an angle with respect to the bottom surface of the supporting portion 104 so as to lead the gas to deliver outwardly. The base portion 110 has a plurality of gas lines 111 and each gas line 111 is connected to one injecting port 107 for supplying the gas to the injecting port 107. As shown in FIG. 1C, the outer wall of the rotary spindle 106 has at least two pieces of protrusions 131 stretching along its vertical axis. Correspondingly, the inner wall of the base portion 110 has at least two slots 132 for holding the protrusions 131. When the spin actuator 115 drives the vacuum chuck 103 to rotate through the rotary spindle 106, the base portion 110 is also driven to rotate as a follower under the same speed of the vacuum chuck 103. So the vacuum chuck 103, the substrate, and the base portion 110 and the supporting portion 104 of the protecting apparatus rotate together during process at a set speed.

The gas supplying apparatus 114 is disposed around the outer wall of the base portion 110 of the protecting apparatus. The gas supplying apparatus 114 is fixed and cannot rotate along with the base portion 110 when the base portion 110 is driven to rotate. In an embodiment, the gas supplying apparatus 114 can be fixed on the bottom of a process chamber. A gas tube 128 of the gas supplying apparatus 114 supplies gas to the gas lines 111 of the protecting apparatus. A mass flow controller 129 is set on the gas tube 128 for gas flow speed control. A gas pressure regulator (not shown) is also applied on the gas tube 128 for gas pressure control.

The vertical actuator 113 drives the spin actuator 115 to move up and down, so as to lead the vacuum chuck 103 to move vertically.

As shown in FIGS. 1A and 1B, when using the apparatus for processing a substrate, particularly, a substrate 101 is bonded on a substrate carrier 102 which is made of semiconductor substrate, glass or sapphire. The vacuum chuck 103 grasps the substrate from its backside by vacuum suction. In this embodiment, the vacuum chuck 103 grasps the substrate carrier 102 on which the substrate 101 is bonded. The vertical actuator 113 drives the spin actuator 115 to move down to a bottom position of the vertical actuator 113. The spin actuator 115 drives the vacuum chuck 103, the substrate carrier 102 and the protecting apparatus to rotate together during process at a set speed of 10 to 3000 RPM. The supporting portion 104 of the protecting apparatus is set very close to the substrate carrier 102 and a gap 105 is formed between the supporting portion 104 and the substrate carrier 102. The plurality of injecting ports 107 delivers a protection gas, such as N₂ or CDA, to the gap 105. The plurality of releasing ports 108 releases the protection gas out of the gap 105, preventing the protection gas from bursting through the space between the bevel of the substrate carrier 102 and the supporting portion 104 to the area above the space. In this case, a positive gas pressure is formed in the gap 105, and the protection gas in the gap 105 serves as a gas curtain to protect the bevel and backside of the substrate carrier 102 during the process. A nozzle 112 dispenses chemical liquid on the front side of the substrate 101, and the gas curtain in the gap 105 prevents the chemical liquid from flowing to the bevel and backside of the substrate carrier 102. Meanwhile, the chemical liquid flows outwardly through the top surface of the supporting portion 104 to a shroud 118 which is disposed around the supporting portion 104 and the chemical liquid is shielded without splashing by the shroud 118. In an embodiment, a wall of the process chamber can be used as the shroud 118. A constant gas pressure in the gap 105 is maintained in a positive value relative to the atmosphere pressure, and it is controlled by the gas flow speed and the gas pressure of the gas lines 111.

As shown in FIG. 1B, the vertical actuator 113 drives the spin actuator 115 to move up to a top position of the vertical actuator 113, which leads the vacuum chuck 103 to move up for keeping a desired vertical distance from the supporting portion 104 for loading or unloading the substrate, herein the substrate carrier 102, or during other rinse steps. In order to ensure the vacuum chuck 103 moving up and down smoothly, a gap 115a is maintained between the rotary spindle 106 and the base portion 110, and another gap 115b is maintained between the vacuum chuck 103 and the supporting portion 104. The gap 115b should be small enough for the positive gas pressure building up in the gap 105 during the substrate bevel and backside protection.

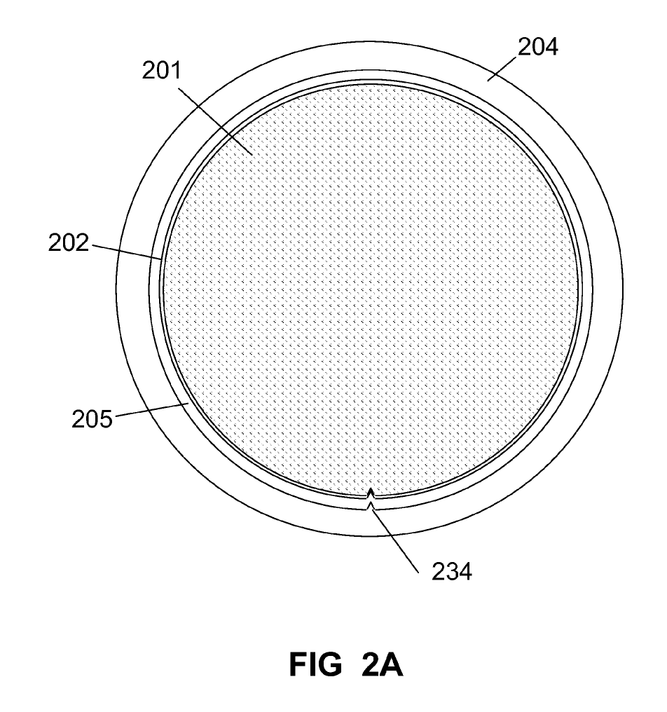

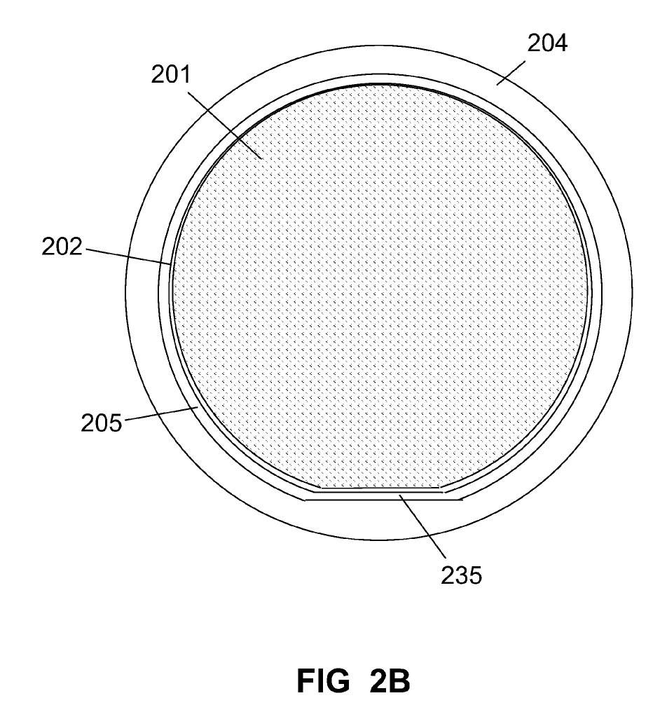

Referring to FIG. 2A and FIG. 2B, for maintaining the size of the gap 205 consistent around the periphery of the substrate carrier 202, a tip shaped protrusion 234 or a flat shaped protrusion 235 is designed on the supporting portion 204 to compensate a notch of the substrate carrier 202. Correspondingly, the substrate 201 which is bonded on the substrate carrier 202 has the same shaped notch. The supporting portion 204 with different shaped protrusion can be easily replaced to match up with different substrate applications. In another embodiment, in order to maintain the top surface of the supporting portion 204 and the substrate carrier 202 at the same horizontal plane, the supporting portion 204 with different thickness can be easily replaced to match up with different substrate carrier applications.

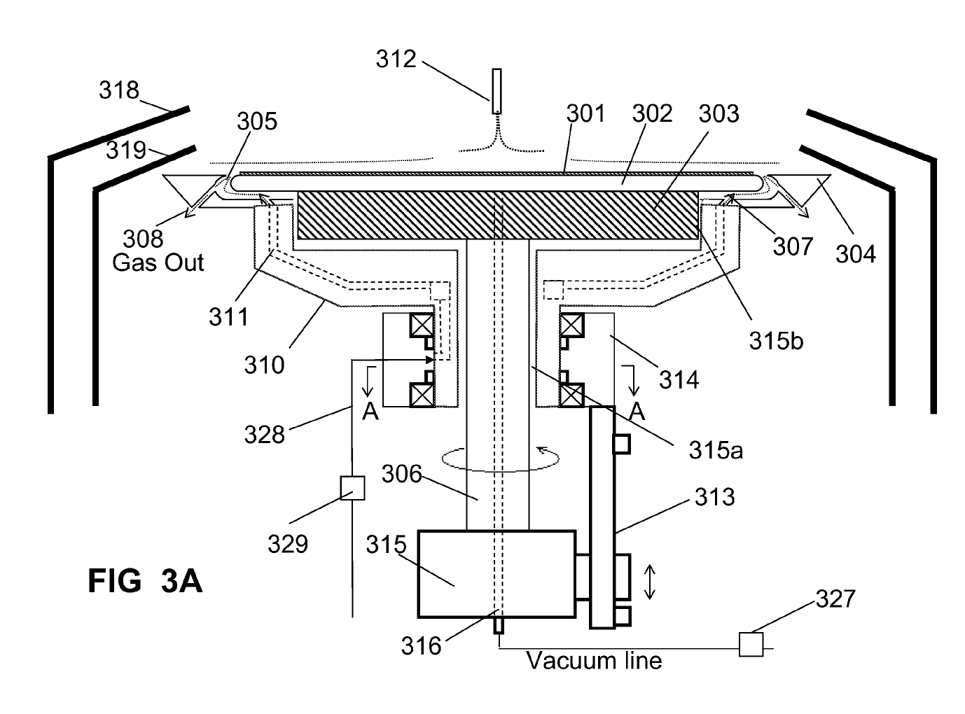

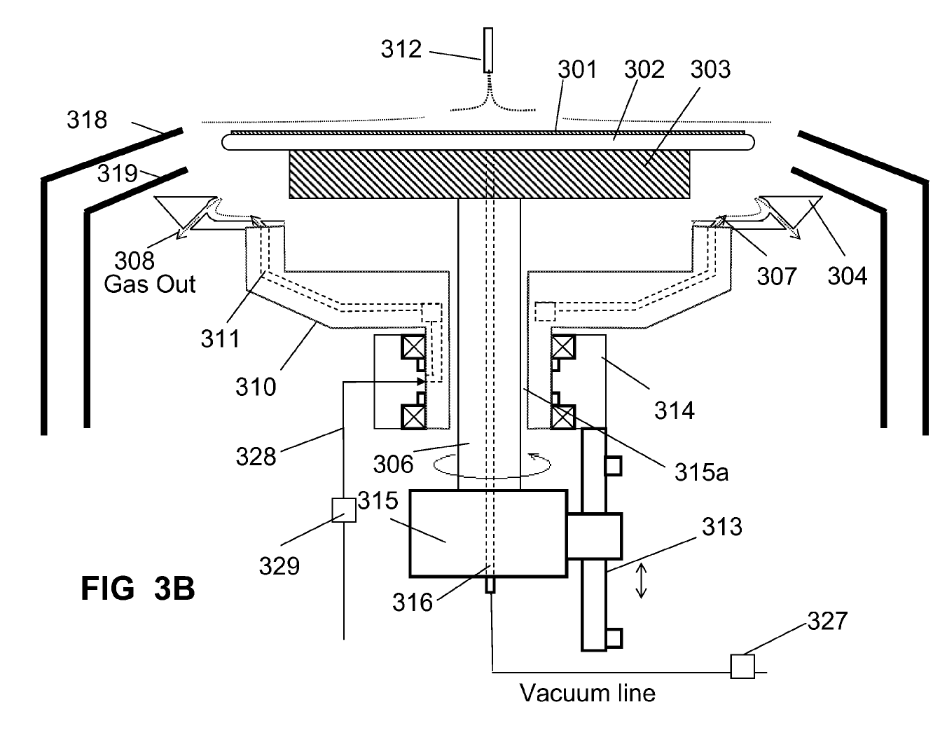

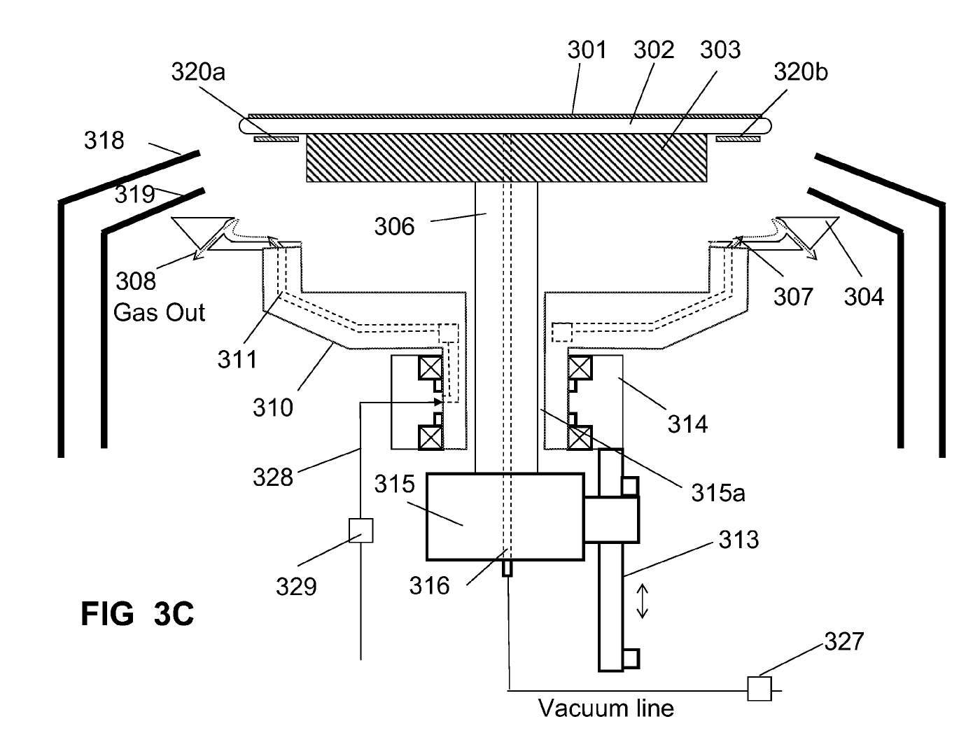

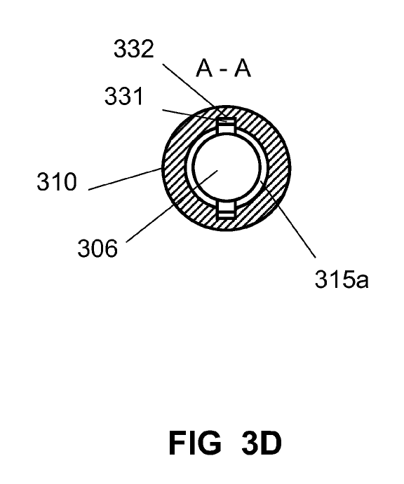

Referring to FIG. 3A to FIG. 3D, an apparatus for substrate bevel and backside protection in accordance with another exemplary embodiment of the present invention is illustrated. The apparatus includes a vacuum chuck 303 for holding and positioning the backside of the substrate by vacuum suction, a protecting apparatus surrounding the periphery of the vacuum chuck 303 for protecting the bevel and backside of the substrate, a gas supplying apparatus 314 supplying gas to the protecting apparatus to form gas curtain for protecting the bevel and backside of the substrate, a spin actuator 315 connecting to the vacuum chuck 303 for driving the vacuum chuck 303 and the protecting apparatus to rotate, a vertical actuator 313 for driving the vacuum chuck 303 to move vertically, and an upper shroud 318 and a lower shroud 319 for shielding different types of process liquids, avoiding the process liquids splashing in different process steps.

The vacuum chuck 303 is connected to the spin actuator 315 through a rotary spindle 306. One end of the rotary spindle 306 is connected to the vacuum chuck 303 and the other end of the rotary spindle 306 is connected to the spin actuator 315. A vacuum line 316 passes though the center of the spin actuator 315 and the center of the rotary spindle 306 and extends to the vacuum chuck 303, so as to provide the vacuum suction for holding and positioning the substrate. A pressure regulator 327 is disposed on the vacuum line 316 for controlling the pressure of the vacuum line 316.

The protecting apparatus includes a base portion 310 and a supporting portion 304 which is mounted on the base portion 310 and detachable from the base portion 310. The supporting portion 304 has a plurality of injecting ports 307 and a plurality of releasing ports 308. The plurality of injecting ports 307 and releasing ports 308 are respectively arranged on a circle on the supporting portion 304. Each injecting port 307 is inclined and formed an angle with respect to the bottom surface of the supporting portion 304 so as to lead the gas to deliver outwardly. The base portion 310 has a plurality of gas lines 311 and each gas line 311 is connected to one injecting port 307 for supplying the gas to the injecting port 307. As shown in FIG. 3D, the outer wall of the rotary spindle 306 has at least two pieces of protrusions 331 stretching along its vertical axis. Correspondingly, the inner wall of the base portion 310 has at least two slots 332 for holding the protrusions 331. When the spin actuator 315 drives the vacuum chuck 303 to rotate through the rotary spindle 306, the base portion 310 is also driven to rotate as a follower under the same speed of the vacuum chuck 303. So the vacuum chuck 303, the substrate, and the base portion 310 and the supporting portion 304 of the protecting apparatus rotate together during process at a set speed.

The gas supplying apparatus 314 is disposed around the outer wall of the base portion 310 of the protecting apparatus. The gas supplying apparatus 314 is fixed and cannot rotate along with the base portion 310 when the base portion 310 is driven to rotate. In an embodiment, the gas supplying apparatus 314 can be fixed on the bottom of a process chamber. A gas tube 328 of the gas supplying apparatus 314 supplies gas to the gas lines 311 of the protecting apparatus. A mass flow controller 329 is set on the gas tube 328 for gas flow speed control. A gas pressure regulator (not shown) is also applied on the gas tube 328 for gas pressure control.

The vertical actuator 313 drives the spin actuator 315 to move up and down, so as to lead the vacuum chuck 303 to move vertically.

As shown in FIGS. 3A to 3C, when using the apparatus for processing a substrate, particularly, a substrate 301 is bonded on a substrate carrier 302 which is made of semiconductor substrate, glass or sapphire. The vacuum chuck 303 grasps the substrate from its backside by vacuum suction. In this embodiment, the vacuum chuck 303 grasps the substrate carrier 302 on which the substrate 301 is bonded. The vertical actuator 313 drives the spin actuator 315 to move down to a bottom position of the vertical actuator 313. The spin actuator 315 drives the vacuum chuck 303, the substrate carrier 302 and the protecting apparatus to rotate together during process at a set speed of 10 to 3000 RPM. The supporting portion 304 of the protecting apparatus is set very close to the substrate carrier 302 and a gap 305 is formed between the supporting portion 304 and the substrate carrier 302. The plurality of injecting ports 307 delivers a protection gas, such as N2 or CDA, to the gap 305. The plurality of releasing ports 308 releases the protection gas out of the gap 305, preventing the protection gas from bursting through the space between the bevel of the substrate carrier 302 and the supporting portion 304 to the area above the space. In this case, a positive gas pressure is formed in the gap 305, and the protection gas in the gap 305 serves as a gas curtain to protect the bevel and backside of the substrate carrier 302 during the process. A nozzle 312 dispenses chemical liquid on the front side of the substrate 301, and the gas curtain in the gap 305 prevents the chemical liquid from flowing to the bevel and backside of the substrate carrier 302. Meanwhile, the chemical liquid flows outwardly through the top surface of the supporting portion 304 to the lower shroud 319 and the chemical liquid is shielded without splashing by the lower shroud 319. A constant gas pressure in the gap 305 is maintained in a positive value relative to the atmosphere pressure, and it is controlled by the gas flow speed and the gas pressure of the gas lines 311.

As shown in FIG. 3B, the vertical actuator 313 drives the spin actuator 315 to move up to a middle position of the vertical actuator 313 and the vacuum chuck 303 moves up along with the spin actuator 315. Then the nozzle 312 dispenses rinsing liquid on the front side of the substrate 301. Because the gap between the supporting portion 304 and the substrate carrier 302 becomes big, so the gas curtain for protecting the bevel and backside of the substrate carrier 302 cannot be formed any more. The rinsing liquid reflows to the bevel and backside of the substrate carrier 302. This step of rinse is used to rinse the bevel and backside of the substrate carrier 302 to ensure no chemical remains. The rinsing liquid is shielded without splashing by the upper shroud 318. The protection gas still keeps supplying to the plurality of injecting ports 307, so as to prevent the splashing rinsing liquid from accumulating on the supporting portion 304 or flowing into the gas lines 311.

As shown in FIG. 3C, the vertical actuator 313 drives the spin actuator 315 to move up to a top position of the vertical actuator 313, which leads the vacuum chuck 303 to move up for keeping a desired vertical distance from the supporting portion 304 for loading or unloading the substrate, herein the substrate carrier 302. In order to ensure the vacuum chuck 303 moving up and down smoothly, a gap 315a is maintained between the rotary spindle 306 and the base portion 310, and another gap 315b is maintained between the vacuum chuck 303 and the supporting portion 304. The gap 315b should be small enough for the positive gas pressure building up in the gap 305 during the substrate bevel and backside protection. Robot arms 320a and 320b are used for loading or unloading the substrate carrier 302 from the backside of the substrate carrier 302.

The present invention utilizes the protecting apparatus to form the gas curtain for protecting the bevel and backside of the substrate, avoiding damaging the bevel and backside of the substrate when the substrate is processed.

The foregoing description of the present invention has been presented for purposes of illustration and description. It is not intended to be exhaustive or to limit the invention to the precise form disclosed, and obviously many modifications and variations are possible in light of the above teaching. Such modifications and variations that may be apparent to those skilled in the art are intended to be included within the scope of this invention as defined by the accompanying claims.

1. An apparatus for substrate bevel and backside protection, comprising:
a vacuum chuck holding and positioning a substrate;
a protecting apparatus having a base portion and a supporting portion, wherein the supporting portion is set close to the substrate and a gap is formed between the supporting portion and the substrate, the supporting portion has a plurality of injecting ports for delivering gas to the gap and a plurality of releasing ports for releasing the gas out of the gap, the base portion has a plurality of gas lines and each gas line is connected to one injecting port;
a gas supplying apparatus supplying the gas to the gas lines of the protecting apparatus, wherein the plurality of injecting ports deliver the gas to the gap for forming a positive gas pressure in the gap, the gas in the gap serve as a gas curtain to protect the bevel and backside of the substrate;
a spin actuator driving the vacuum chuck and the protecting apparatus to rotate; and
a vertical actuator driving the vacuum chuck to move vertically.

2. The apparatus as claimed in claim 1, wherein the plurality of injecting ports and releasing ports are respectively arranged on a circle on the supporting portion.

3. The apparatus as claimed in claim 1, wherein each injecting port is inclined and formed an angle with respect to the bottom surface of the supporting portion so as to lead the gas to deliver outwardly.

4. The apparatus as claimed in claim 1, wherein the supporting portion is mounted on the base portion and detachable from the base portion.

5. The apparatus as claimed in claim 1, wherein the vacuum chuck is connected to the spin actuator through a rotary spindle.

6. The apparatus as claimed in claim 5, wherein the outer wall of the rotary spindle has at least two pieces of protrusions stretching along its vertical axis, the inner wall of the base portion has at least two slots for holding the protrusions, when the spin actuator drives the vacuum chuck to rotate through the rotary spindle, the base portion is also driven to rotate as a follower under the same speed of the vacuum chuck.

7. The apparatus as claimed in claim 5, further comprising a vacuum line passing though the center of the spin actuator and the center of the rotary spindle and extending to the vacuum chuck to provide a vacuum suction for holding and positioning the substrate.

8. The apparatus as claimed in claim 7, further comprising a pressure regulator disposed on the vacuum line for controlling the pressure of the vacuum line.

9. The apparatus as claimed in claim 1, wherein the gas supplying apparatus is disposed around the outer wall of the base portion of the protecting apparatus, the gas supplying apparatus is fixed and does not rotate along with the base portion when the base portion is driven to rotate.

10. The apparatus as claimed in claim 1, wherein the gas supplying apparatus includes a gas tube for supplying the gas to the gas lines of the protecting apparatus.

11. The apparatus as claimed in claim 10, further comprising a mass flow controller set on the gas tube for gas flow speed control.

12. The apparatus as claimed in claim 10, further comprising a gas pressure regulator applied on the gas tube for gas pressure control.

13. The apparatus as claimed in claim 1, wherein a constant gas pressure in the gap is maintained and is controlled by the gas flow speed and the gas pressure of the gas lines.

14. The apparatus as claimed in claim 1, wherein the vertical actuator drives the spin actuator to move up and down, so as to lead the vacuum chuck to move vertically.

15. The apparatus as claimed in claim 14, wherein the vertical actuator drives the spin actuator to move down to a bottom position of the vertical actuator, a chemical liquid is dispensed on the substrate, a shroud shields the chemical liquid, avoiding the chemical liquid splashing.

16. The apparatus as claimed in claim 14, wherein the vertical actuator drives the spin actuator to move up to a middle position of the vertical actuator, a rinsing liquid is dispensed on the substrate for rinsing the bevel and backside of the substrate, the rinsing liquid is shielded without splashing by another shroud.

17. The apparatus as claimed in claim 16, wherein when the rinsing liquid is dispensed on the substrate for rinsing the bevel and backside of the substrate, the gas still keeps supplying to the plurality of injecting ports, so as to prevent the rinsing liquid from accumulating on the supporting portion or flowing into the gas lines.

18. The apparatus as claimed in claim 14, wherein the vertical actuator drives the spin actuator to move up to a top position of the vertical actuator, which leads the vacuum chuck to move up for keeping a desired vertical distance from the supporting portion for loading or unloading the substrate.

19. The apparatus as claimed in claim 1, wherein the supporting portion of the protecting apparatus has a tip shaped protrusion or a flat shaped protrusion to compensate a notch of the substrate.

20. The apparatus as claimed in claim 1, wherein the supporting portion of the protecting apparatus is replaceable according to different requirements.

21. The apparatus as claimed in claim 1, wherein the size of the gap maintains consistent around the periphery of the substrate.

22. The apparatus as claimed in claim 1, wherein the top surface of the supporting portion of the protecting apparatus and the substrate are at the same horizontal plane.
